(19) United States
(12) Patent Application Publication
(10) Pub. No.: US 2015/0267959 A1
(43) Pub. Date: Sep. 24, 2015

(54) GAS BARRIER FILM, REFRIGERATOR HAVING THE SAME AND METHOD OF MANUFACTURING GAS BARRIER FILM

(71) Applicants: Samsung Electronics Co., Ltd., Gyeonggi-do (KR); Konkuk University Industrial Cooperation Corp., Seoul (KR)

(72) Inventors: Seon-Yeong Kim, Gyeonggi-do (KR); Yo-Sep Min, Gyeonggi-do (KR); Seung Hoon Kal, Gyeonggi-do (KR); Seung Jin Oh, Seoul (KR); Inhye Park, Seoul (KR); Jina Leem, Seoul (KR)

(21) Appl. No.: 14/666,029

(22) Filed: Mar. 23, 2015

(30) Foreign Application Priority Data
Mar. 21, 2014 (KR) 10-2014-0033687

(51) Int. Cl. F25D 23/06; C23C 16/40; C23C 16/455

(52) U.S. Cl. CPC F25D 23/066; C23C 16/45525; C23C 16/45527; C23C 16/403; F25D 23/062; F25D 2201/12

(57) ABSTRACT

Provided herein is a gas barrier film having excellent flexibility and an excellent gas barrier characteristic at the same time and a refrigerator having the same. Provided herein is a method of manufacturing a gas barrier film. The gas barrier film includes an organic-inorganic mixed layer on which a first organic-inorganic hybrid layer including a first organic part and a first inorganic part and an aluminum oxide layer are laminated. The gas barrier film also includes a second organic-inorganic hybrid layer including a second organic part and a second inorganic part. The gas barrier film further includes a substrate on which the organic-inorganic mixed layer and the second organic-inorganic hybrid layer are laminated.

### CROSS-REFERENCE TO RELATED APPLICATION(S) AND CLAIM OF PRIORITY

The present application is related to and claims the benefit of Korean Patent Application No. 10-2014-0033687, filed on Mar. 21, 2014 in the Korean Intellectual Property Office, the disclosure of which is incorporated herein by reference.

### TECHNICAL FIELD

Embodiments of this disclosure relate to a gas barrier film having an improved structure for increasing flexibility and a gas transmission preventing effect, a refrigerator having the same, and a method of manufacturing a gas barrier film.

### BACKGROUND

An outer wall of a door or a main body uses an insulating material in order to insulate a refrigerator. An insulating material in the related art such as a polyurethane has a thermal conductivity of about 20 W/(mK) (Watts per meter Kelvin). When this insulating material is used, an outer wall of the refrigerator becomes thicker, and a storage capacity of the refrigerator decreases. Therefore, in view of the above-described problems, a vacuum insulation panel having a thermal conductivity that is to 1/10 or less that of polyurethane has recently been used. The vacuum insulation panel includes a core material made of a porous material and a sheath material made of a gas barrier film that surrounds the core material and maintains a vacuum state of an inside thereof. A characteristic of the gas barrier film forming the sheath material has a significant influence on performance of the vacuum insulation panel. In order to implement low power consumption and increase a storage capacity, the development of a gas barrier film having excellent flexibility and a gas barrier effect is necessary.

### SUMMARY

There are provided a gas barrier film having excellent flexibility and an excellent gas barrier characteristic at the same time, a refrigerator having the same, and a method of manufacturing a gas barrier film.

To address the above-discussed deficiencies, it is a primary object to provide a gas barrier film, including: an organic-inorganic mixed layer on which a first organic-inorganic hybrid layer including an organic part and an inorganic part and an aluminum oxide layer are laminated; a second organic-inorganic hybrid layer including an organic part and an inorganic part; and a substrate on which the organic-inorganic mixed layer and the second organic-inorganic hybrid layer are laminated.

The organic part included in the first organic-inorganic hybrid layer and the organic part included in the second organic-inorganic hybrid layer includes a hydrocarbon derivative having 5 carbon atoms. The first organic-inorganic hybrid layer and the second organic-inorganic hybrid layer includes a compound including a unit expressed as a chemical formula of [Al—O—(CH₂)₅—O]ₙ. A thickness of the organic-inorganic mixed layer is selected from a range of 3 nm to 7 nm. A thickness of the first organic-inorganic hybrid layer is selected from a range of 3 nm to 7 nm. The substrate includes a polymer film having a thickness selected from a range of 10 μm to 100 μm. The substrate further includes an aluminum layer that is deposited on the polymer film. The substrate further includes a protection layer that is formed on the aluminum layer and includes at least one resin selected from the group including acryl and a polyethylene.

In a first embodiment, there is provided a method to manufacture a gas barrier film according to an atomic layer deposition process including a method to manufacture a first organic-inorganic hybrid layer. The method includes supplying a first precursor including trimethyl aluminum (TMA) to a substrate and depositing the precursor thereon. The method also includes supplying an inert gas to remove an undeposited first precursor or reaction byproducts. The method further includes supplying a second precursor including a hydrocarbon derivative having 5 carbon atoms to the substrate on which the first precursor is deposited and depositing the precursor thereon. The method includes supplying the inert gas to remove an undeposited second precursor or reaction byproducts. The second precursor includes 1,5-pentanediol. The first organic-inorganic hybrid layer includes a compound including a unit expressed as a chemical formula of [Al—O—(CH₂)₅—O]ₙ.

The method to manufacture an organic-inorganic mixed layer, the method including a method to manufacture a second organic-inorganic hybrid layer in which a first sub-cycle is performed one or more times is provided. The first sub-cycle includes supplying the first precursor including trimethyl aluminum (TMA) onto the substrate and depositing the precursor thereon. The first sub-cycle also includes supplying the inert gas to remove the undeposited first precursor or reaction byproducts. The sub-cycle further includes supplying the second precursor including a hydrocarbon derivative having 5 carbon atoms onto the substrate on which the first precursor is deposited and depositing the precursor thereon. The sub-cycle includes supplying the inert gas to remove the undeposited second precursor or reaction byproducts.

A method to manufacture an aluminum oxide layer in which a second sub-cycle is performed one or more times is provided. The second sub-cycle includes supplying the first precursor including trimethyl aluminum (TMA) onto the substrate and depositing the precursor thereon. The second sub-cycle includes supplying the inert gas to remove the undeposited first precursor or reaction byproducts. The second sub-cycle also includes supplying the second precursor including water vapor (H₂O) onto the substrate on which the first precursor is deposited and depositing the precursor thereon. The second sub-cycle further includes supplying the inert gas to remove the undeposited second precursor or reaction byproducts. The second precursor used in the method of manufacturing an organic-inorganic mixed layer may include 1,5-pentanediol. The second organic-inorganic hybrid layer may include a compound including a unit expressed as a chemical formula of [Al—O—(CH₂)₅—O]ₙ.

In the method to manufacture a first organic-inorganic hybrid layer and the method to manufacture an organic-inorganic mixed layer, a deposition temperature is selected from a range of about room temperature (such as about 22° C.) to about 120° C. In the method to manufacture a first organic-inorganic hybrid layer and the method to manufacture an organic-inorganic mixed layer, a deposition temperature is selected from a range of about room temperature (such as about 22° C.) to about 80° C. In the method to manufacture an organic-inorganic mixed layer, a super cycle is performed one or more times. The cycle includes a method to manufacture a second organic-inorganic hybrid layer in which the first sub-cycle is performed one or more times. A method to manufacture an aluminum oxide layer in which the second sub-cycle is performed one or more times. The X may be 1 and Y may be 3. The first organic-inorganic hybrid layer and the organic-inorganic mixed layer can be alternately laminated. The organic-inorganic mixed layer includes a thickness selected from a range of about 3 nm to about 7 nm. The first organic-inorganic hybrid layer includes a thickness selected from a range of about 3 nm to about 7 nm.

In a second embodiment, a refrigerator is provided. The refrigerator includes an outer case forming an appearance. The refrigerator also includes an inner case provided inside the outer case and fanning a storage container. The refrigerator further includes a vacuum insulation panel provided between the outer case and the inner case. The vacuum insulation panel includes a gas barrier film. The gas barrier film includes an organic-inorganic mixed layer on which a first organic-inorganic hybrid layer including an organic part and an inorganic part and an aluminum oxide layer are laminated. The gas barrier film also includes a second organic-inorganic hybrid layer including an organic part and an inorganic part. The gas barrier film further includes a substrate on which the organic-inorganic mixed layer and the second organic-inorganic hybrid layer are laminated.

The organic part included in the first organic-inorganic hybrid layer and the organic part included in the second organic-inorganic hybrid layer includes a hydrocarbon derivative having 5 carbon atoms. The first organic-inorganic hybrid layer and the second organic-inorganic hybrid layer includes a compound including a unit expressed as a chemical formula of [Al—O—(CH₂)₅—O]ₙ.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a perspective view of an example refrigerator according to this disclosure;

FIG. 2 is a cross sectional view of an example refrigerator according to this disclosure;

FIG. 3 is a cross sectional view of a component of an example refrigerator according to this disclosure;

FIG. 4 is a cross sectional view of an example vacuum insulation panel according to this disclosure;

FIG. 5 is a diagram illustrating an example atomic layer deposition method applied to form a gas barrier film according to this disclosure;

FIG. 6 is a flowchart illustrating an example method of manufacturing a gas barrier film according to this disclosure;

FIG. 7 is a flowchart illustrating an example method of manufacturing an aluminum oxide layer according to this disclosure;

FIGS. 8A and 8B are flowcharts illustrating an example method of manufacturing an organic-inorganic mixed layer according to this disclosure;

FIG. 9 is a cross sectional view schematically illustrating an example structure of a gas barrier film including both an organic-inorganic mixed layer and an organic-inorganic hybrid layer according to this disclosure;

FIG. 10 illustrates a graph showing an example result that is obtained by measuring a thickness of a thin film while an exposure time of pentanediol increases according to this disclosure;

FIGS. 11 and 12 illustrate example graphs showing a result that is obtained by measuring a water vapor transmission rate and an oxygen transmission rate of a gas barrier film according to this disclosure;

FIG. 13 illustrates an example graph showing a result that is obtained by measuring a water vapor transmission rate of a gas barrier film and a water vapor transmission rate of a gas barrier film according to this disclosure;

FIG. 14 illustrates an example graph showing a result that is obtained by measuring a water vapor transmission rate and an oxygen transmission rate of a gas barrier film according to this disclosure; and

FIG. 15 illustrates an example graph showing a result that is obtained by measuring a water vapor transmission rate of a gas barrier film according to this disclosure.

### DETAILED DESCRIPTION

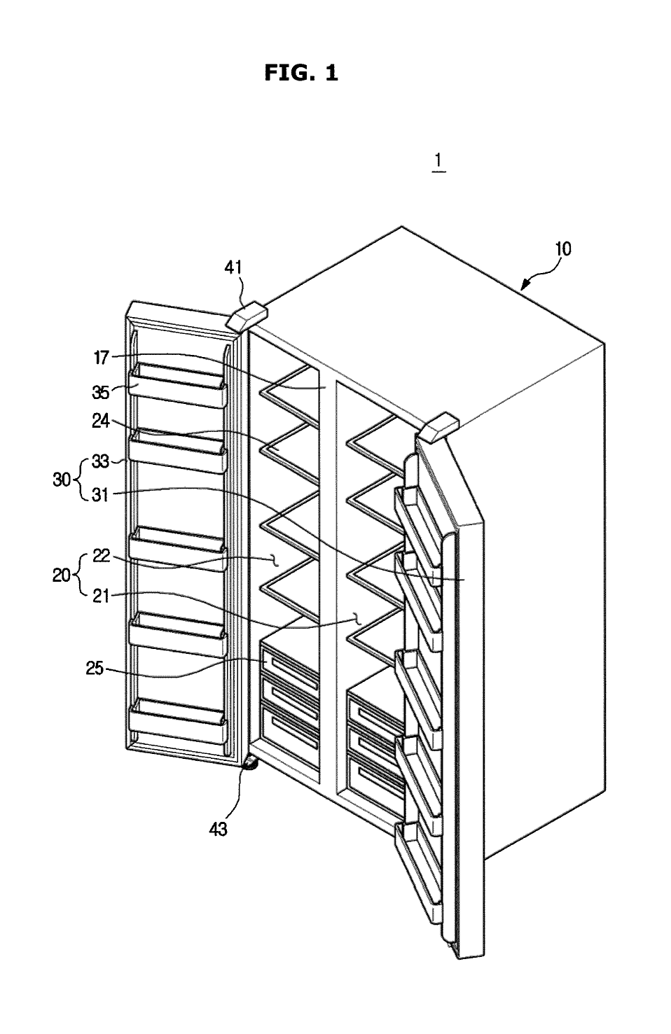

FIGS. 1 through 15, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged insulating or sealing device. Hereinafter, embodiments of a gas barrier film, a refrigerator having the same, and a method of manufacturing a gas barrier film according to an aspect will be described in detail with reference to the accompanying drawings.

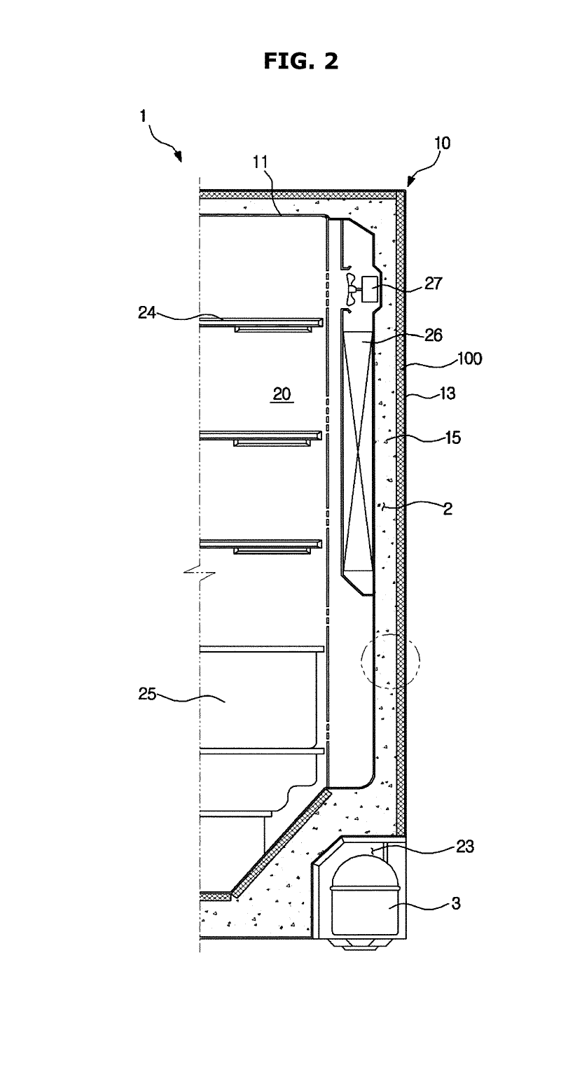

FIG. 1 is a perspective view of an example refrigerator according to this disclosure. FIG. 2 is a cross sectional view of an example refrigerator according to this. As illustrated in FIGS. 1 and 2, a refrigerator 1 includes a main body 10 forming an appearance and a storage container 20 that is provided in the main body 10 and has a front or door that is configured to open. The main body 10 includes an inner case 11 forming the storage container 20 and an outer case 13 forming an appearance, and includes a cold air supply device configured to supply cold air to the storage container 20. The cold air supply device includes a compressor 3, a condenser, an expansion valve, an evaporator 26, an exhaust fan 27, or the like. The compressor 3 is configured to compress a refrigerant and condense the compressed refrigerant. A machine chamber 23 in which the condenser is installed is provided at a bottom rear side of the main body 10. The storage container 20 is divided into left and right sides by a partition wall 17. A refrigerator unit 21 is provided in the right side of the main body 10 and a freezer unit 22 is provided in the left side of the main body 10.

The refrigerator 1 further includes a door 30 configured to open and close the storage container 20. The refrigerator unit 21 and the freezer unit 22 are opened and closed by a refrigerator unit door 31 and a freezer unit door 33 that are pivotally combined with the main body 10, respectively. A plurality of door guards 35 is provided at the rear of the refrigerator unit door 31 and the freezer unit door 33 to accommodate food or the like. A plurality of shelves 24 are provided in the storage container 20 and divide the storage container 20 into a plurality of parts. Goods such as food are stacked on the shelf 24. In addition, a plurality of storage boxes 25 are provided to be inserted into and removed from the storage container 20 in a sliding manner. The refrigerator 1 further includes an upper hinge 41 and a lower hinge 43 that allow the door 30 to be rotatably combined with the main body 10.

A foam space 2 is provided between the inner case 11 forming the storage container 20 and the outer case 13 that is combined with the outside of the inner case 11 and forms an appearance. A foam insulating material 15 is filled in the foam space 2. A foam insulating material, a foam plastic-based insulating material, such as a polyurethane foam, and a polyethylene foam are used. In order to enhance an insulating property of the foam insulating material 15, a vacuum insulation panel (VIP) 100 is filled along with the foam insulating material 15.

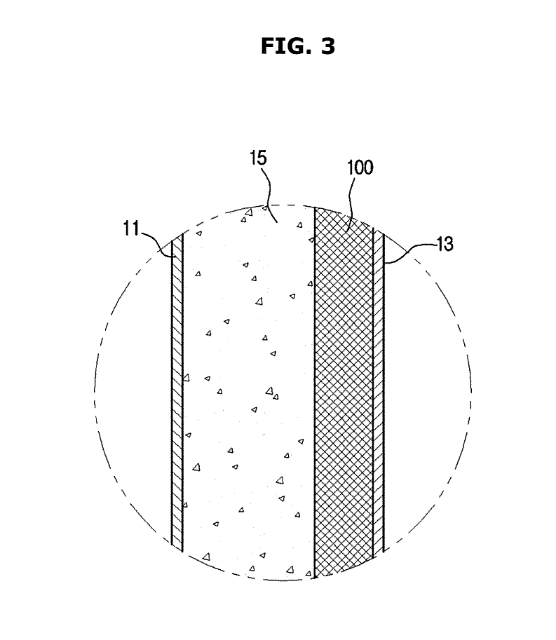

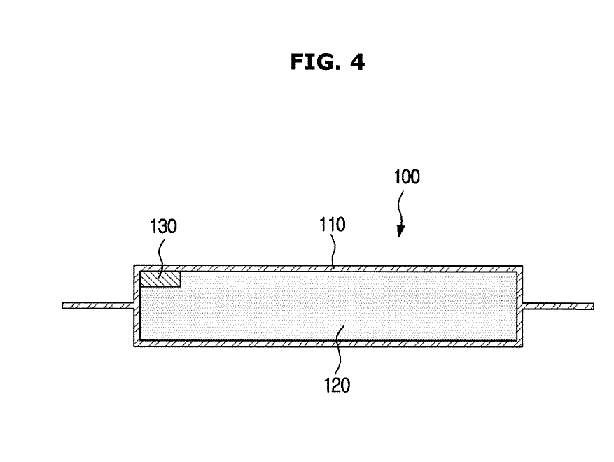

FIG. 3 is a cross sectional view of a component of an example refrigerator according to this disclosure. FIG. 4 is a cross sectional view of an example vacuum insulation panel according to this disclosure. The vacuum insulation panel 100 includes a core material 120 that is a porous material and forms an internal vacuum space and a sheath material 110 that surrounds the core material 120 and maintains an internal vacuum state. The sheath material 110 blocks fine gases and water from penetrating into an inside in a vacuum state and maintains a lifespan of the vacuum insulation panel 100.

The core material 120 includes a glass fiber having excellent insulation performance. When the core material 120 has a structure in which panels woven by a slender glass fiber are laminated, it is possible to obtain a high insulation effect. Specifically, as a pore size between glass fibers decreases, since an influence of radiation is minimized, a high insulation effect is expected.

Meanwhile, the core material 120 includes silica. Even when silica is used for a longer time than the glass fiber, it has less change in performance and therefore has an excellent characteristic in terms of long-term reliability. The vacuum insulation panel 100 further includes a getter 130. The getter 130 is provided inside the core material 120, and absorbs at least one of a gas and water that are introduced into the core material 120 to maintain a vacuum state of the core material 120. The getter 130 is in a powder form, and is formed to have a predetermined block or rectangular parallelepiped shape. In addition, the getter 130 is applied to an inner surface of the sheath material 110 or to a surface of the core material 120, or is inserted into the core material 120. The getter 130 is made of a material such as CaO, BaO, or MgO, and includes a catalyst. Meanwhile, as described above, the sheath material 110 is made of a gas barrier film since fine gases and water penetrating into the core material 120 in a vacuum state should be blocked. Hereinafter, in the following embodiment, the sheath material 110 made of a gas barrier film will be described.

As a sheath material in the related art, an aluminum foil sheath material or an aluminum deposited sheath material is generally used. The aluminum foil sheath material has excellent durability since external fine gases and water are effectively blocked by a thick aluminum layer, but there is a problem of a heat bridge in which heat flows through edges. In addition, the aluminum deposited sheath material has a thinner aluminum layer than the aluminum foil sheath material, has no heat bridge, but has a problem in that a blocking property of external fine gases and water decreases, a fine pin hole is generated when the sheath material is folded or bent and durability decreases. A gas barrier film 110 according to an embodiment is formed by an atomic layer deposition (ALD) process in order to ensure an excellent gas barrier effect, durability, and flexibility.

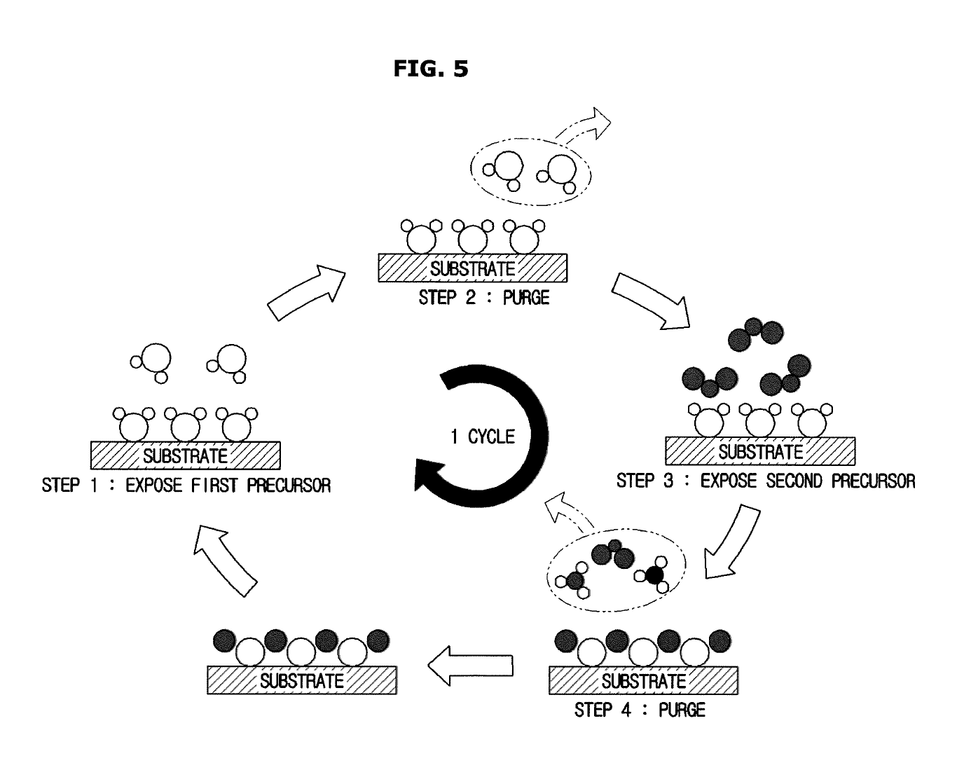

FIG. 5 is a diagram illustrating example processes of an atomic layer deposition method applied to form a gas barrier film according to this disclosure. The atomic layer deposition method is a vapor deposition method in which an oxide, a nitride, a metal thin film, and the like are grown through self-limiting chemisorption. In an atomic layer deposition process, an appropriate precursor vapor and a reaction gas are alternately exposed to a substrate to deposit an atomic layer, and deposition of the atomic layer is repeated in order to perform deposition to a desired thickness. In this case, a thin film growth occurs through chemisorption between gas molecules and a reactive functional group of a surface of the substrate.

As illustrated in FIG. 5, one cycle of the atomic layer deposition method is composed of four steps. First, in step 1, a first precursor is supplied to a chamber in which a substrate is provided, and the substrate is exposed to the first precursor. The supplied first precursor reacts with a surface of the substrate and performs chemisorption. Accordingly, an atomic layer of the first precursor is deposited on the surface of the substrate. When adsorption areas of the surface of the substrate are saturated, no reaction occurs any longer when an extra precursor is supplied. This is referred to as self-limiting chemisorption. In step 2, while the first precursor does not react with the surface of the substrate any longer, an inert gas such as Ar or N₂ is supplied to remove the extra first precursor and reaction byproducts. This is referred to as purge.

In step 3, a second precursor is supplied to the chamber and the substrate is exposed to the second precursor. Here, the second precursor refers to a reaction gas. The supplied second precursor reacts with the first precursor adsorbed onto the surface of the substrate and performs chemisorption. When adsorption areas of the surface of the substrate are saturated by the second precursor, no reaction occurs any longer. In step 4, the inert gas is supplied to the chamber again to remove the extra second precursor and reaction byproducts. One cycle includes the processes of steps 1 to 4. When the cycle is repeated, an atomic layer thin film of a desired thickness grows. According to self-limiting chemisorption in step 1 and step 3, it is possible to perform excellent thickness control and uniform growth across a large area and form a conformal film on a 3D structure. Meanwhile, in the atomic layer deposition process applied to the method of manufacturing the gas barrier film 110, a deposition temperature is selected from a range of room temperature (such as about 22° C.) to about 120° C., and more specifically, from a range of room temperature (such as about 22° C.) to about 80° C.

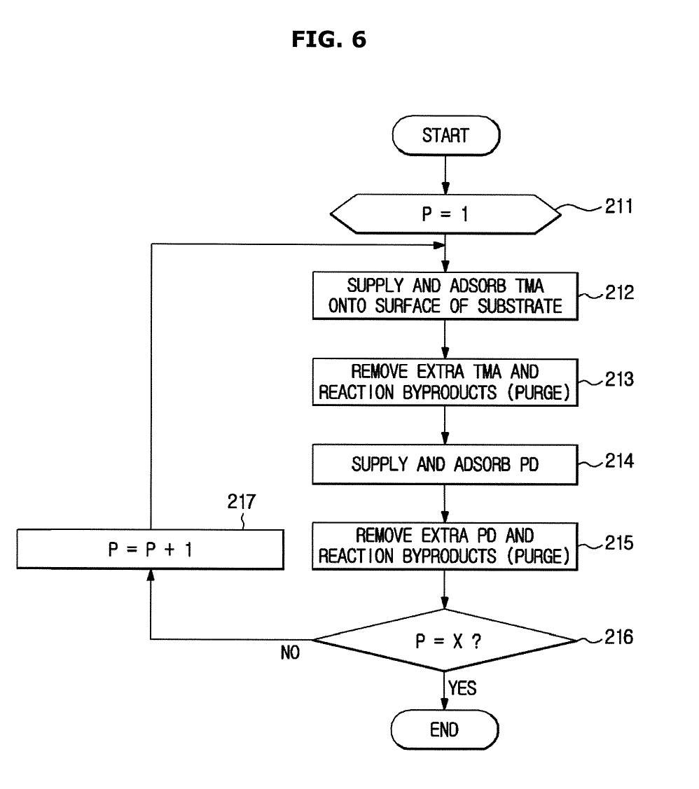

FIG. 6 is a flowchart illustrating an example method of manufacturing a gas barrier film according to this disclosure. As described above, the gas barrier film 110 is manufactured by applying the atomic layer deposition process. First, a first cycle of the atomic layer deposition process starts (211). For this purpose, trimethyl aluminum (TMA) is supplied as the first precursor and adsorbed onto the surface of the substrate (212). The supplied TMA reacts with the surface of the substrate and performs chemisorption. Accordingly, a TMA layer is deposited onto the surface of the substrate. When adsorption areas of the surface of the substrate are saturated, no reaction occurs any longer even when extra TMA is supplied.

Then, purge is performed such that the inert gas is supplied to remove extra TMA and reaction byproducts (213). When extra TMA and reaction byproducts are completely removed, pentanediol (PD) is supplied as the second precursor and adsorbed onto the surface of the substrate (214). Names of pentanediols are classified according to a position in the pentane of a carbon atom with which a hydroxyl group is combined among carbon atoms and characteristics thereof are different. In this embodiment, 1,5-pentanediol in which the hydroxyl group is combined with first and fifth carbon atoms is used. The supplied pentanediol reacts with TMA adsorbed onto the surface of the substrate and performs chemisorption. Here, a compound including a unit expressed as a chemical formula of [Al—O—(CH₂)₅—O]ₙ is generated. Also, when adsorption areas of the surface of the substrate are saturated, no reaction occurs any longer.

Purge is performed such that the inert gas is supplied to remove extra pentanediol and reaction byproducts (215). Operations 212 to 215 correspond to steps 1 to 4 of one cycle of the above atomic layer deposition process, respectively. According to a desired thickness of the gas barrier film 110, the cycle is performed one or more times. For this purpose, operations 212 to 215 are repeated one or more times (216 and 217). A compound layer including a unit of [Al—O—(CH₂)₅—O]ₙ formed in the substrate according to the above process in FIG. 6 is formed through chemisorption of pentanediol serving as an organic material and TMA serving as an inorganic material and includes an organic part and an inorganic part. Therefore, the layer is referred to as an organic-inorganic hybrid layer.

Therefore, the gas barrier film 110 includes the organic-inorganic hybrid layer. The organic material used to form the organic-inorganic hybrid layer is a hydrocarbon derivative having 5 carbon atoms, and as a specific example, 1,5-pentanediol is used. Meanwhile, the gas barrier film 110 further includes an organic-inorganic mixed layer. The organic-inorganic mixed layer includes an aluminum oxide layer serving as an inorganic layer and the organic-inorganic hybrid layer. Hereinafter, a method of manufacturing an organic-inorganic mixed layer will be described in detail.

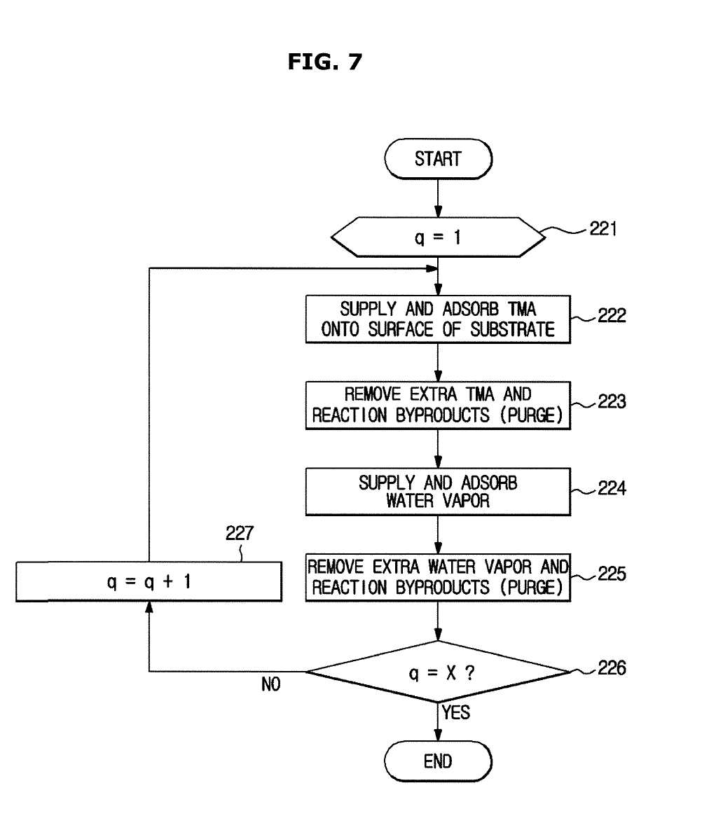

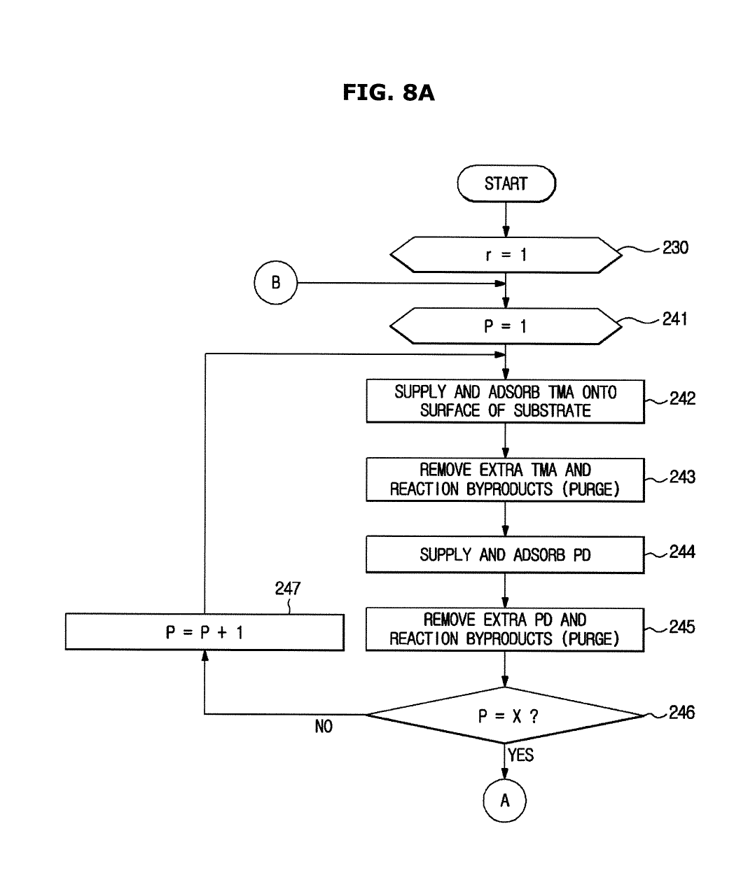

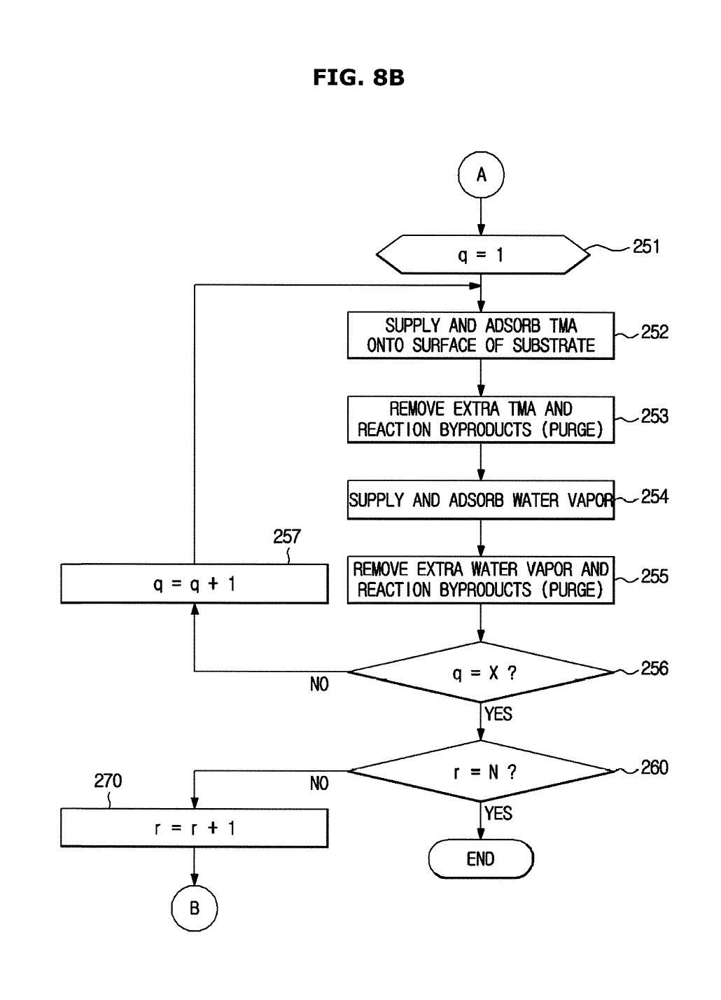

FIG. 7 is a flowchart illustrating an example method of manufacturing an aluminum oxide layer according to this disclosure. FIGS. 8A and 8B are flowcharts illustrating an example method of manufacturing an organic-inorganic mixed layer according to this disclosure. The aluminum oxide layer is also manufactured by applying the atomic layer deposition process. As illustrated in FIG. 7, first, the first cycle of the atomic layer deposition process starts (221). For this purpose, trimethyl aluminum (TMA) is supplied as the first precursor and adsorbed onto the surface of the substrate (222). The supplied TMA reacts with the surface of the substrate and performs chemisorption. Accordingly, a TMA layer is deposited onto the surface of the substrate. When adsorption areas of the surface of the substrate are saturated, no reaction occurs any longer even when extra TMA is supplied.

Then, purge is performed such that the inert gas is supplied to remove extra TMA and reaction byproducts (223). When extra TMA and reaction byproducts are completely removed, water vapor (H₂O) is supplied as the second precursor and adsorbed onto the surface of the substrate (224). The water vapor reacts with TMA adsorbed onto the surface of the substrate and performs chemisorption. Here, Al₂O₃ is generated. Also, when adsorption areas of the surface of the substrate are saturated, no reaction occurs any longer.

Purge is performed such that the inert gas is supplied to remove extra water vapor and reaction byproducts (225). Operations 222 to 225 correspond to steps 1 to 4 of one cycle of the above atomic layer deposition process, respectively. According to a desired thickness of the gas barrier film 110, the cycle is performed one or more times (Y). For this purpose, operations 222 to 225 are repeated one or more times (Y) (226 and 227).

The organic-inorganic mixed layer includes the organic-inorganic hybrid layer that is generated by repeating the cycle of growing a thin film using TMA and pentanediol one or more times (X) and the aluminum oxide layer that is generated by repeating the cycle of growing a thin film using TMA and water vapor one or more times (Y). Therefore, the organic-inorganic mixed layer is generated by repeating a super cycle including one or more times (X) of a sub-cycle for generating the organic-inorganic hybrid layer and one or more times (X) of a sub-cycle for generating the aluminum oxide layer. Hereinafter, description will be made in detail with reference to FIG. 8.

As illustrated in FIGS. 8A and 8B, first, a first super cycle starts (230). For this purpose, a first sub-cycle for generating the organic-inorganic hybrid layer starts (241). Trimethyl aluminum (TMA) is supplied as the first precursor and adsorbed onto the surface of the substrate (242). The supplied TMA reacts with the surface of the substrate and performs chemisorption. Accordingly, a TMA layer is deposited onto the surface of the substrate. When adsorption areas of the surface of the substrate are saturated, no reaction occurs any longer even when extra TMA is supplied.

Then, purge is performed such that the inert gas is supplied to remove extra TMA and reaction byproducts (243). When extra TMA and reaction byproducts are completely removed, 1,5-pentanediol (PD) is supplied as the second precursor and adsorbed onto the surface of the substrate (244). The supplied 1,5-pentanediol reacts with TMA adsorbed onto the surface of the substrate and performs chemisorption. Here, a compound including a unit expressed as a chemical formula of [Al—O—(CH₂)₅—O]ₙ is generated. Also, when adsorption areas of the surface of the substrate are saturated, no reaction occurs any longer.

Purge is performed such that the inert gas is supplied to remove extra pentanediol and reaction byproducts (245). Then, operations 242 to 245 are repeated one or more times (X) (246 and 247). When operations 242 to 245 are repeatedly performed one or more times (X), a second sub-cycle for generating the aluminum oxide layer starts (251). Trimethyl aluminum (TMA) is supplied as the first precursor and adsorbed onto the surface of the substrate (252). The supplied TMA reacts with the surface of the substrate and performs chemisorption. Accordingly, a TMA layer is deposited onto the surface of the substrate. When adsorption areas of the surface of the substrate are saturated, no reaction occurs any longer even when extra TMA is supplied.

Then, purge is performed such that the inert gas is supplied to remove extra TMA and reaction byproducts (253). When extra TMA and reaction byproducts are completely removed, water vapor (H2O) is supplied as the second precursor and adsorbed onto the surface of the substrate (254). The water vapor reacts with TMA adsorbed onto the surface of the substrate and performs chemisorption. Here, Al2O3 is generated. Also, when adsorption areas of the surface of the substrate are saturated, no reaction occurs any longer. Purge is performed such that the inert gas is supplied to remove extra water vapor and reaction byproducts (255). Then, operations 252 to 255 are repeated one or more times (Y) (256 and 257).

When operations 252 to 255 are repeated one or more times (Y), one super cycle for generating the organic-inorganic mixed layer is completed. Therefore, in the organic-inorganic mixed layer, a small amount of [Al—O—(CH2)5-O] is included in Al2O3 in units of an atomic layer. When the super cycle including one or more times (X) of a sub-cycle and one or more times (Y) of a sub-cycle is repeated one or more times (N) (260 and 270), the organic-inorganic mixed layer is generated. The organic-inorganic mixed layer generated in this manner is referred to as an X:Y ratio mixed layer. A thickness and a composition of the X:Y ratio mixed layer is freely controlled by adjusting how many times a super cycle or a sub-cycle is repeated. Meanwhile, the gas barrier film 110 according to the embodiment includes the organic-inorganic mixed layer and the organic-inorganic hybrid layer, and improves flexibility and a gas barrier effect at the same time. Hereinafter, a structure thereof will be described in detail.

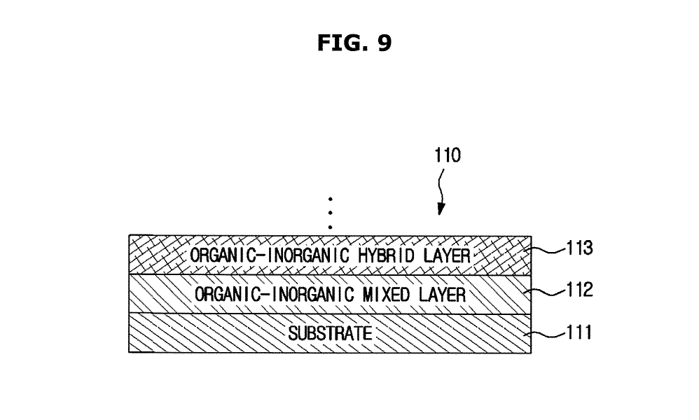

FIG. 9 is a cross sectional view schematically illustrating an example structure of a gas barrier film including both an organic-inorganic mixed layer and an organic-inorganic hybrid layer according to this disclosure. As illustrated in FIG. 9, the gas barrier film 110 has a structure in which an organic-inorganic mixed layer 112 and an organic-inorganic hybrid layer 113 are laminated on a substrate 111. Here, the organic-inorganic mixed layer 112 is the X:Y ratio mixed layer manufactured by the process in FIG. 8 and the organic-inorganic hybrid layer 113 is manufactured by the process in FIG. 6. However, X applied to manufacture the organic-inorganic mixed layer 112 and X applied to manufacture the organic-inorganic hybrid layer 113 is different from each other or the same. In addition, lamination of the organic-inorganic mixed layer 112 and the organic-inorganic hybrid layer 113 is also performed by the atomic layer deposition process. As an example of the substrate 111 used herein, a polymer film having a thickness selected from a range of 10 to 100 μm is used.

While FIG. 9 illustrates an example of an organic-inorganic hybrid layer 113 that is laminated on an organic-inorganic mixed layer 112 according to this disclosure. A lamination sequence or the number of laminations of the organic-inorganic mixed layer 112 and the organic-inorganic hybrid layer 113 has no limitation. Hereinafter, a more specific structure and physical property of the gas barrier film 110 will be described with reference to detailed examples and experimental examples. However, the following embodiments and experimental examples are for the purpose of describing the present disclosure only and are not intended to limit the scope of the disclosure.

First, four types of substrates used for examples of the gas barrier film 110 were prepared according to the following [Table 1].

TABLE 1

| Substrate Sign | Configuration |
|---|---|
| A | PET(thickness: 12 μm) |
| B | Al(100 nm)/PET |
| C | Acryl/Al(200 nm)/PET |
| D | PET/Al(100 nm)/PET/Al(100 nm)/LLDPE |

As shown in [Table 1], a substrate A is a PET film having a thickness of about 12 μm. In a substrate B, an aluminum layer having a thickness of about 100 nm is deposited on the PET film. In a substrate 3, an aluminum layer having a thickness of about 200 nm is deposited on the PET film and acryl is laminated thereon. In a substrate D, an aluminum layer having a thickness of about 100 nm and PET are alternately laminated on a linear low-density polyethylene (LLDPE). As shown in the following [Table 2], the organic-inorganic mixed layer was deposited on the substrate A at slightly different thicknesses around 20 nm at a temperature of about 80° C. or about 120° C.

TABLE 2

| | | | Approximate | |
|---|---|---|---|---|
| | Sub- | | Deposition | Approximate |
| | strate | Film Configuration | Temperature | Thickness |
| Example 1 | A | 1:1 organic-inorganic | 80° C. | 16 nm |
| | | ratio mixed layer | | |
| Example 2 | A | 1:3 organic-inorganic | 80° C. | 21 nm |
| | | ratio mixed layer | | |
| Example 3 | A | 1:5 organic-inorganic | 80° C. | 21 nm |
| | | ratio mixed layer | | |
| Example 4 | A | 1:7 organic-inorganic | 80° C. | 20 nm |
| | | ratio mixed layer | | |
| Example 5 | A | 1:1 organic-inorganic | 120° C. | 18 nm |
| | | ratio mixed layer | | |
| Example 6 | A | 1:3 organic-inorganic | 120° C. | 25 nm |
| | | ratio mixed layer | | |
| Example 7 | A | 1:5 organic-inorganic | 120° C. | 26 nm |
| | | ratio mixed layer | | |
| Example 8 | A | 1:7 organic-inorganic | 120° C. | 21 nm |
| | | ratio mixed layer | | |

As shown in the following [Table 3], the organic-inorganic mixed layer was deposited on the substrate B at slightly different thicknesses of about 20 nm at a temperature of about 80° C.

TABLE 3

| | | | Approximate | |
|---|---|---|---|---|
| | Sub- | | Deposition | Approximate |
| | strate | Film Configuration | Temperature | Thickness |
| Example 9 | B | 1:3 organic-inorganic | 80° C. | 16 nm |
| | | ratio mixed layer | | |
| Example | B | 1:3 organic-inorganic | 80° C. | 20 nm |
| 10 | | ratio mixed layer | | |
| Example | B | 1:5 organic-inorganic | 80° C. | 26 nm |
| 11 | | ratio mixed layer | | |
| Example | B | 1:5 organic-inorganic | 80° C. | 23 nm |
| 12 | | ratio mixed layer | | |

As shown in the following [Table 4], the organic-inorganic mixed layer or the organic-inorganic hybrid layer was deposited on the substrate 3 at slightly different thicknesses of about 20 nm.

TABLE 4

| | Sub- | | Approximate |
|---|---|---|---|
| | strate | Film Configuration | Thickness |
| Example 13 | C | 1:3 organic-inorganic ratio mixed | 20 nm |
| | | layer | |
| Example 14 | C | 1:3 organic-inorganic ratio mixed | 20 nm |
| | | layer | |
| Example 15 | C | organic-inorganic hybrid layer | 20 nm |
| Example 16 | C | organic-inorganic hybrid layer | 21 nm |
| Example 17 | C | organic-inorganic hybrid layer | 15 nm |

As shown in the following [Table 5], a gas barrier film of 3 layers was manufactured by sequentially laminating the organic-inorganic mixed layer, the aluminum layer, and the organic-inorganic mixed layer on the substrate 3 at different thicknesses.

TABLE 5

| | | | Approximate |
|---|---|---|---|
| | Sub- | | Total |
| | strate | Film Configuration | Thickness |
| Example | C | 1:3 organic-inorganic ratio mixed layer | 10 nm |
| 18 | | Al₂O₃ | |
| | | 1:3 organic-inorganic ratio mixed layer | |
| Example | C | 1:3 organic-inorganic ratio mixed layer | 14 nm |
| 19 | | Al₂O₃ | |
| | | 1:3 organic-inorganic ratio mixed layer | |
| Example | C | 1:3 organic-inorganic ratio mixed layer | 15 nm |
| 20 | | Al₂O₃ | |
| | | 1:3 organic-inorganic ratio mixed layer | |
| Example | C | 1:3 organic-inorganic ratio mixed layer | 36 nm |
| 21 | | Al₂O₃ | |
| | | 1:3 organic-inorganic ratio mixed layer | |
| Example | C | 1:3 organic-inorganic ratio mixed layer | 70 nm |
| 22 | | Al₂O₃ | |
| | | 1:3 organic-inorganic ratio mixed layer | |

As shown in the following [Table 6], the organic-inorganic mixed layer and the organic-inorganic hybrid layer were laminated on the substrate 3 at different thicknesses.

TABLE 6

| | | | Approximate |
|---|---|---|---|
| | Sub- | | Total |
| | strate | Film Configuration | Thickness |
| Example | C | 1:3 organic-inorganic ratio mixed layer | 13 nm |
| 23 | | organic-inorganic hybrid layer | |
| | | 1:3 organic-inorganic ratio mixed layer | |
| Example | C | 1:3 organic-inorganic ratio mixed layer | 17 nm |
| 24 | | organic-inorganic hybrid layer | |
| | | 1:3 organic-inorganic ratio mixed layer | |
| Example | C | 1:3 organic-inorganic ratio mixed layer | 26 nm |
| 25 | | organic-inorganic hybrid layer | |
| | | 1:3 organic-inorganic ratio mixed layer | |
| Example | C | 1:3 organic-inorganic ratio mixed layer | 62 nm |
| 26 | | organic-inorganic hybrid layer | |
| | | 1:3 organic-inorganic ratio mixed layer | |

As shown in the following [Table 7], the organic-inorganic hybrid layer and the aluminum oxide layer were laminated on the substrate 3 at different thicknesses.

TABLE 7

| | | | Approximate |
|---|---|---|---|
| | Substrate | Film Configuration | Total Thickness |
| Example | C | organic-inorganic hybrid layer | 16 nm |
| 27 | | Al₂O₃ | |
| | | organic-inorganic hybrid layer | |
| Example | C | organic-inorganic hybrid layer | 40 nm |
| 28 | | Al₂O₃ | |
| | | organic-inorganic hybrid layer | |
| Example | C | organic-inorganic hybrid layer | 57 nm |
| 29 | | Al₂O₃ | |
| | | organic-inorganic hybrid layer | |

As shown in the following [Table 8], by changing the number of deposition layers, the organic-inorganic hybrid layer and the aluminum layer were laminated on the substrate D.

TABLE 8

| | | | Number of | |
|---|---|---|---|---|
| | | | Deposition | Approximate |
| | Substrate | Film Configuration | Layers | Thickness |
| Example | D | 1:3 organic-inorganic | 5 layers | 27 nm |
| 30 | | ratio mixed layer | | |
| | | . | | |
| | | . | | |
| | | . | | |
| | | organic-inorganic | | |
| | | hybrid layer | | |
| | | 1:3 organic-inorganic | | |
| | | ratio mixed layer | | |
| Example | D | 1:3 organic-inorganic | 9 layers | 45 nm |
| 31 | | ratio mixed layer | | |
| | | . | | |
| | | . | | |
| | | . | | |
| | | organic-inorganic | | |
| | | hybrid layer | | |
| | | 1:3 organic-inorganic | | |
| | | mixed layer | | |

As shown in the following [Table 9], Al2O3 was deposited on the substrate 3 at slightly different thicknesses of about 20 nm.

TABLE 9

| | | | Approximate |
|---|---|---|---|
| | Substrate | Film Configuration | Thickness |
| Comparative Example 1 | C | Al₂O₃ | 23 nm |
| Comparative Example 2 | C | Al₂O₃ | 25 nm |
| Comparative Example 3 | C | Al₂O₃ | 27 nm |

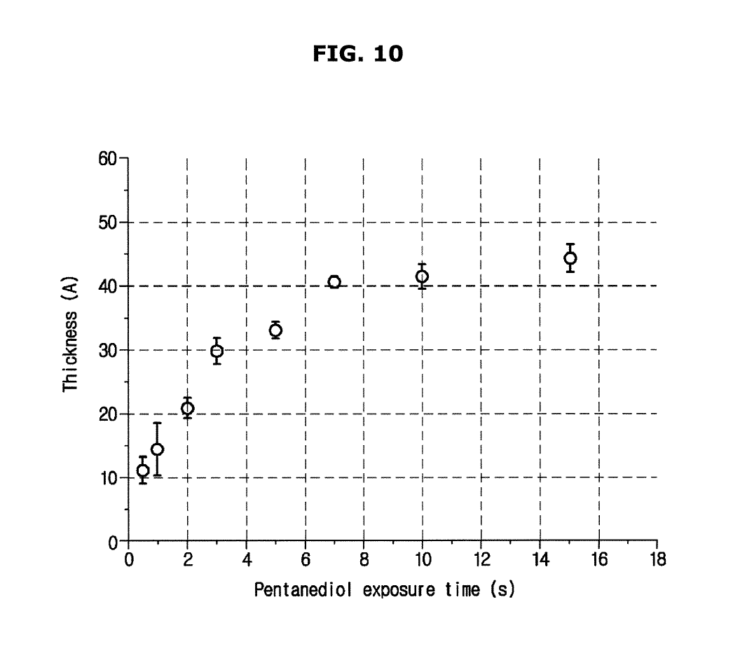

First, in order to check a self-limiting thin film growth behavior according to the atomic layer deposition process, the atomic layer deposition process using TMA and pentanediol as a precursor was performed 50 cycles (X=50) at a temperature of about 120° C. and the organic-inorganic hybrid layer was formed. FIG. 10 illustrates a graph showing a result that is obtained by measuring a thickness of a thin film while an exposure time of pentanediol increases according to this disclosure. As shown in FIG. 10, when the exposure time of pentanediol is greater than 7 seconds, the thickness of the organic-inorganic hybrid layer does not increase any longer. Accordingly, when pentanediol is chemically adsorbed onto the surface of the substrate and adsorption areas of the surface of the substrate are saturated, a self-limiting thin film growth behavior in which no reaction occurs even when extra pentanediol is supplied is checked.

A water vapor transmission rate and an oxygen transmission rate of the substrates shown in [Table 1] were measured. The water vapor transmission rate (WVTR) was measured at about 38° C. and a 100% moisture condition using MOCON Acuatran Model 1. The oxygen transmission rate (OTR) was measured at room temperature (such as about 22° C.) and a 0% (oxygen 100%) moisture condition using MOCON Ox-tran Model 2/21. The measurement results are shown in [Table 10].

TABLE 10

| Substrate Sign | WVTR (g/m² per day) | OTR (cc/m² per day) |
|---|---|---|
| A | 62.12 | 148.58 |
| B | 0.278 | 0.230 |
| C | 0.135 | 0.229 |
| D | 0.020 | — |

For reference, as the WVTR and the OTR decrease, it represents that oxygen blocking performance and water blocking performance of the substrate are excellent. As shown in [Table 10], it is understood that the substrate A made of PET is vulnerable to transmission of water and oxygen, and the substrate B and the substrate 3 including PET in which aluminum is deposited have significantly improved blocking performance of water and oxygen. However, it is understood that the substrate 3 showed almost no change in the oxygen transmission rate even when the thickness at which the aluminum was deposited was increased to twice that of the substrate B, and thus oxygen blocking performance did not improve. This shows that oxygen is generally transmitted through a pin hole and the pin hole may not be decreased when a thickness of the aluminum layer is simply increased. On the other hand, it is understood that the substrate D in which aluminum and PET are laminated has a significantly decreased water vapor transmission rate and thus water blocking performance is significantly improved.

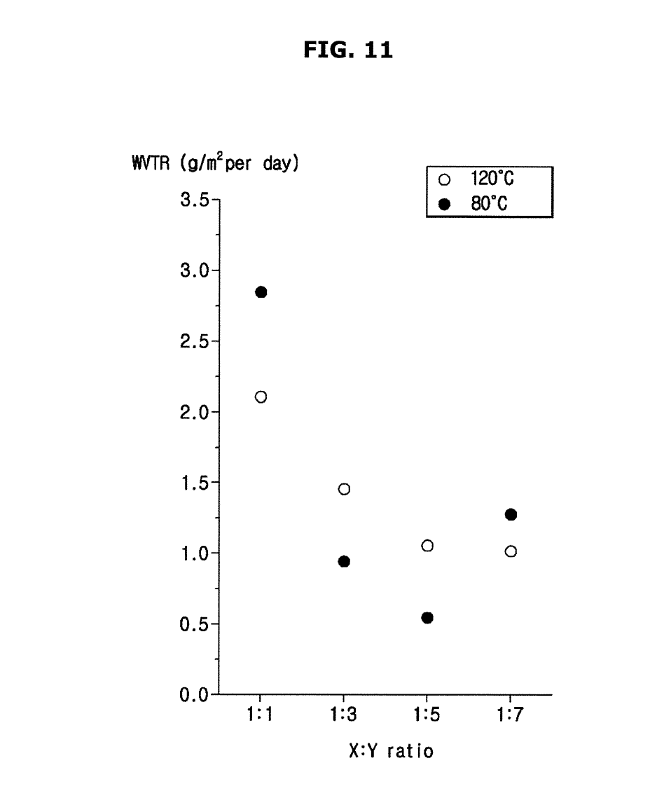

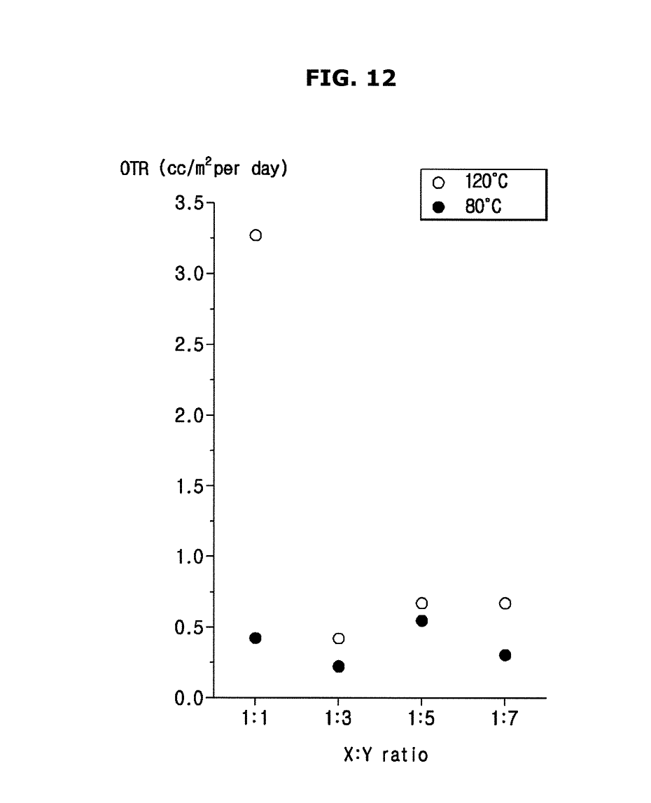

The results obtained by measuring a water vapor transmission rate and an oxygen transmission rate of the gas barrier film 110 according to Examples 1 to 8 shown in [Table 2] are shown in [Table 11] and FIGS. 11 and 12.

TABLE 11

| | WVTR (g/m² per day) | OTR (cc/m² per day) |
|---|---|---|
| Example 1 | 2.8488 | 0.4270 |
| Example 2 | 0.9412 | 0.2194 |
| Example 3 | 0.5460 | 0.5747 |
| Example 4 | 1.2748 | 0.2999 |
| Example 5 | 2.1070 | 3.2708 |
| Example 6 | 1.4552 | 0.4154 |
| Example 7 | 1.0563 | 0.6848 |
| Example 8 | 1.0150 | 0.6885 |

Referring to [Table 11] and FIGS. 11 and 12 compared to the results in [Table 10], while the organic-inorganic mixed layer of only about 20 nm is deposited on the substrate A, the water vapor transmission rate and the oxygen transmission rate were significantly decreased. It is understood that water blocking performance and oxygen blocking performance are significantly improved. However, as shown in FIGS. 11 and 12, it is understood that more excellent performance is shown at a deposition temperature of 80° C. than 120° C. This is because a PET substrate is thermally deformed at 120° C. during deposition. Therefore, when PET is used as the substrate, it is preferable that the deposition temperature be set to a temperature of less than 120° C.

A smaller X value and a greater Y value in an X:Y organic-inorganic ratio mixed layer represent that a greater inorganic part is included in the mixed layer. As shown in FIG. 11, examples in which a 1:1 organic-inorganic ratio mixed layer in which a large content of the organic part is included show a higher water vapor transmission rate than other examples. This represents that water blocking performance is lower than that of the other examples. Based on the result, it is understood that the content of the organic part should not be too large if both water blocking performance and oxygen blocking performance are to be improved. Referring to the results shown in FIGS. 11 and 12, it is understood that the example including the 1:3 organic-inorganic ratio mixed layer and the example including the 1:5 organic-inorganic ratio mixed layer have excellent water blocking and oxygen blocking performance.

The results obtained by measuring a water vapor transmission rate and an oxygen transmission rate of the gas barrier film 110 according to Examples 9 to 12 shown in [Table 3] are shown in [Table 12].

TABLE 12

| | WVTR (g/m² per day) | OTR (cc/m² per day) |
|---|---|---|
| Example 9 | 1.1866 | 0.2211 |
| Example 10 | 1.4029 | 2.6471 |
| Example 11 | 2.9033 | 5.1476 |
| Example 12 | 1.2357 | 0.2182 |

As shown in [Table 12], it is understood that Examples 11 and 12 in which the 1:5 organic-inorganic ratio mixed layer is included have a larger deviation of data according to the thickness than Examples 9 and 10 in which the 1:3 organic-inorganic ratio mixed layer is included. In particular, the oxygen transmission rate has a very large deviation. Meanwhile, since a substrate B has no additional protection layer on the aluminum layer, it was observed that the gas barrier film is damaged after a transmission rate experiment (in particular, a water vapor transmission rate experiment) is performed. This is because there is a big difference between thermal expansion coefficients of aluminum and PET, and thus defects such as cracks are generated in the aluminum layer or an interface thereof is partially detached during a process of depositing the organic-inorganic mixed layer on the substrate B at about 80° C. Therefore, when the substrate including the aluminum layer is used as the substrate of the atomic layer deposition process, it is preferable that a protection layer be formed on the aluminum layer. As the organic-inorganic mixed layer to be deposited, a 1:3 organic-inorganic ratio mixed layer, for example in which the content of the organic part is great, is more advantageous than a 1:5 organic-inorganic ratio mixed layer.

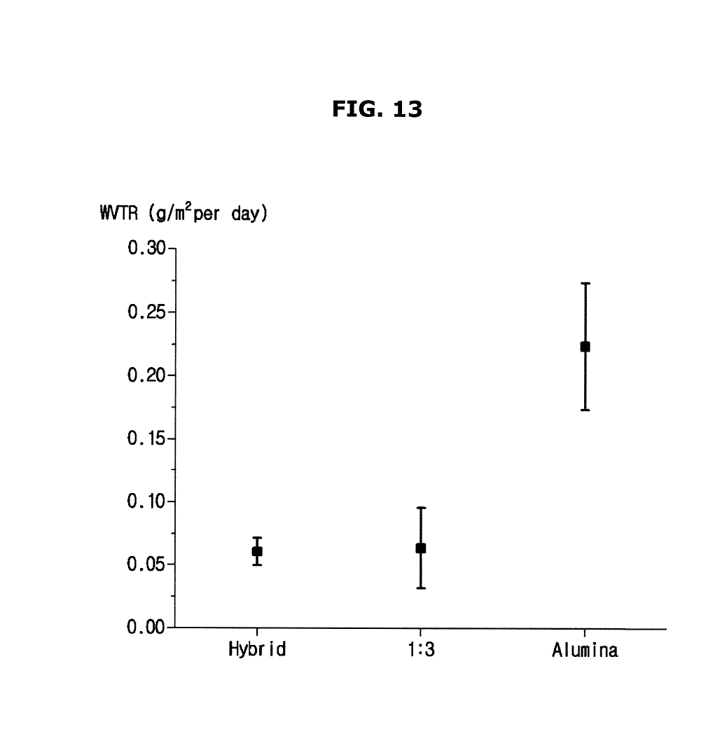

The results obtained by measuring a water vapor transmission rate of the gas barrier film according to Examples 13 to 17 shown in [Table 4] and a water vapor transmission rate of the gas barrier film according to Comparative Examples 1 to 3 shown in [Table 9] were shown in [Table 13] and FIG. 13.

TABLE 13

| | WVTR (g/m² per day) |
|---|---|
| Example 13 | 0.041 |
| Example 14 | 0.085 |
| Example 15 | 0.068 |
| Example 16 | 0.065 |
| Example 17 | 0.048 |
| Comparative Example 1 | 0.286 |
| Comparative Example 2 | 0.175 |
| Comparative Example 2 | 0.240 |
| Comparative Example 3 | 0.192 |

As shown in [Table 13] and the graph of FIG. 13, the gas barrier films according to Comparative Examples 1 to 3 have a higher water vapor transmission rate than the gas barrier films according to Examples 13 to 17. It was presumed that, since the substrate 3 used in Comparative Examples 1 to 3 is a very thin polymer film, it was easily damaged due to a brittle characteristic of Al2O3 and cracks occurred. On the other hand, Examples 13 and 14 in which the 1:3 organic-inorganic ratio mixed layer is included show a relatively excellent water blocking characteristic, and Examples 15, 16, and 17 in which the organic-inorganic hybrid layer is included obtains the most excellent water blocking characteristic having a low deviation. Accordingly, it is understood that pentanediol serving as the organic material precursor used in Examples 13 to 17 ensures flexibility and blocks water transmission.

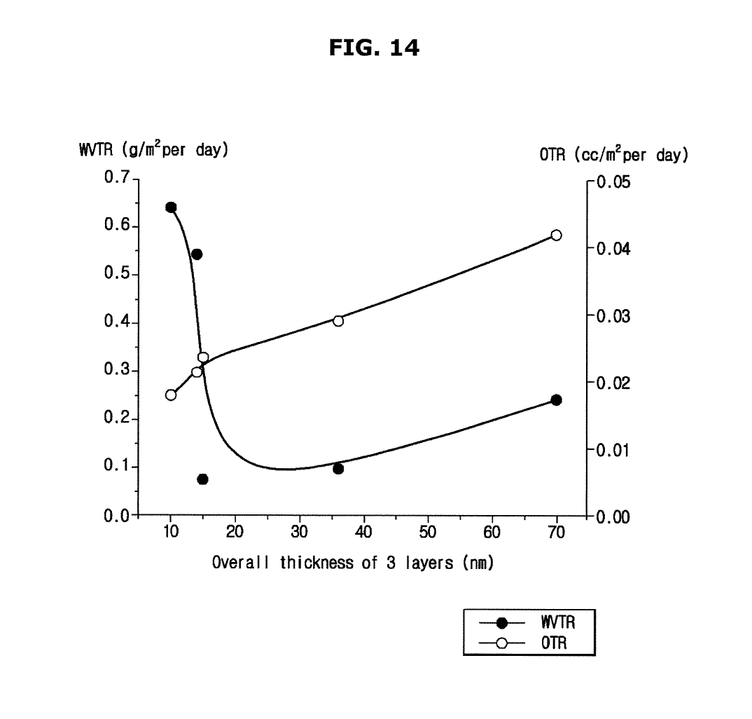

The results obtained by measuring a water vapor transmission rate and an oxygen transmission rate of the gas barrier film according to Examples 18 to 22 shown in [Table 5] were shown in [Table 14] and the graph of FIG. 14.

TABLE 14

| | WVTR (g/m² per day) | OTR (cc/m² per day) |
|---|---|---|
| Example 18 | 0.641 | 0.0179 |
| Example 19 | 0.543 | 0.0213 |
| Example 20 | 0.074 | 0.0235 |
| Example 21 | 0.097 | 0.0290 |
| Example 22 | 0.243 | 0.0418 |

As shown in [Table 14] and the graph of FIG. 14, in the measurement results of Examples 20 to 22, as an entire film becomes thinner, more excellent oxygen blocking performance is obtained. It is understood that, as the thickness decreases, the film becomes more flexible and a possibility of occurrence of cracks in a handling process decreases. It is understood that, as the thickness decreases, water blocking performance becomes more excellent for the same reason. However, it is understood that water transmission is significantly increased in the measurement results of Examples 18 and 19 in which an entire thickness decreases to 15 nm or less. This is considered to be caused by the fact that water is transmitted through not only a physical path such as cracks and a pin hole but is also able to be dispersed and transmitted through the film itself. Therefore, when each thin film layer is laminated, it is preferable that a thickness of each thin film layer be maintained at about 5 nm.

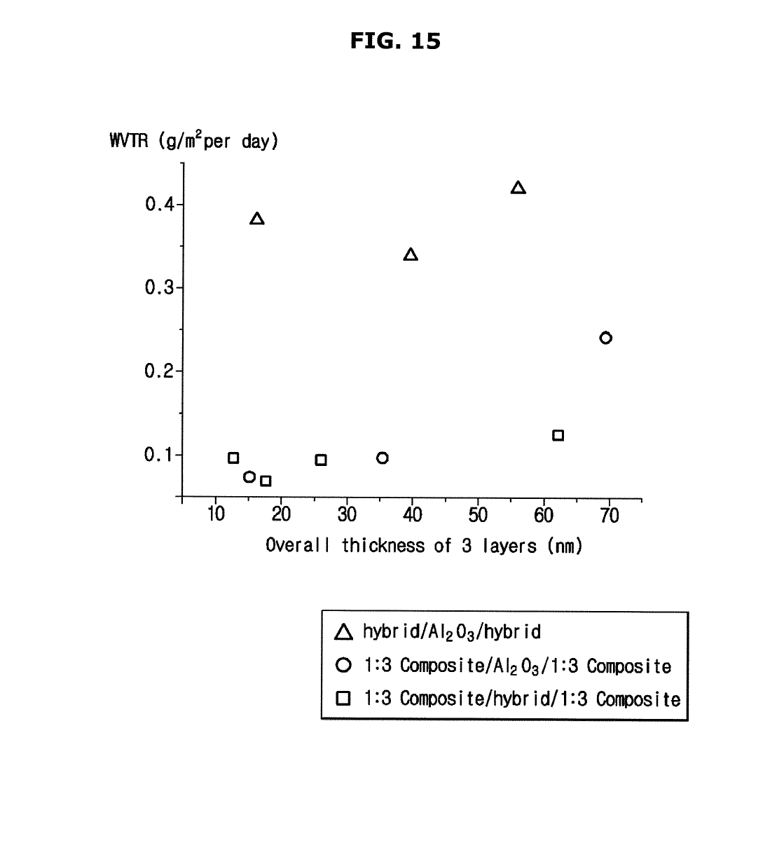

The results obtained by measuring a water vapor transmission rate of the gas barrier films according to Examples 23 to 26 shown in [Table 6], the gas barrier films according to Examples 27 to 29 shown in [Table 7], and the gas barrier films according to Examples 20 to 22 were shown in the graph of FIG. 15. As shown in the graph of FIG. 15, it is understood that, when an entire thickness is 70 nm or less, the gas barrier film (Examples 27 to 29) in which the organic-inorganic hybrid layer, the aluminum oxide layer, and the organic-inorganic hybrid layer are sequentially laminated is vulnerable to water transmission regardless of the thickness, compared to gas barrier films of two different structures.

On the other hand, it is understood that the gas barrier film (Examples 20 to 22) in which a 1:3 organic-inorganic ratio mixed layer, an Al₂O₃ layer, and a 1:3 organic-inorganic ratio mixed layer are sequentially laminated and the gas barrier film (Examples 23 to 26) in which a 1:3 organic-inorganic ratio mixed layer, an organic-inorganic hybrid layer, and a 1:3 organic-inorganic ratio mixed layer are sequentially laminated have relatively excellent water blocking performance. In particular, the gas barrier film (Examples 23 to 26) in which a 1:3 organic-inorganic ratio mixed layer, an organic-inorganic hybrid layer, and a 1:3 organic-inorganic ratio mixed layer are sequentially laminated shows a stable characteristic across a large area to an area having an entire thickness of about 13 nm to about 62 nm. This is because, even if the entire thickness is relatively increased, occurrence of cracks and like in a handling process is suppressed due to a structure in which the organic-inorganic hybrid layer ensuring flexibility and the organic-inorganic mixed layer having excellent water blocking performance are laminated.

The results obtained by measuring a water vapor transmission rate of the gas barrier film according to Examples 30 and 31 shown in [Table 8] were shown in [Table 15].

TABLE 15

| | WVTR (g/m² per day) |
|---|---|
| Example 30 | 0.00621 |
| Example 31 | 0.00151 |

As shown in [Table 10] showing the results of Experimental Example 2, the water vapor transmission rate of the substrate D in which the organic-inorganic mixed layer or the organic-inorganic hybrid layer is not formed is about 0.020 g/m² per day. On the other hand, the gas barrier films (Examples 30 and 31) in which the organic-inorganic mixed layer and the organic-inorganic hybrid layer are laminated on the substrate D as 5 layers and 9 layers as shown in [Table 15] have a water vapor transmission rate of about 0.00621 g/m² per day and about 0.00151 g/m² per day. That is, it is understood that, when the organic-inorganic mixed layer and the organic-inorganic hybrid layer are laminated as multiple layers, water blocking performance is significantly improved. In particular, it is understood that an entire thickness of the gas barrier film of 9 layers (Example 31) is only about 45 nm but the water vapor transmission rate decreases and approaches a measurement threshold value of a measurement device. According to the gas barrier film, the refrigerator having the same, and the method of manufacturing a gas barrier film according to the embodiment, it is possible to obtain excellent flexibility and an excellent gas barrier characteristic at the same time.

Although the present disclosure has been described with an exemplary embodiment, various changes and to one skilled in the art. It is intended that the present disclosure encompass such changes and modifications as fall within the scope of the appended claims.

What is claimed is:

1. A gas barrier film, comprising:
an organic-inorganic mixed layer on which a first organic-inorganic hybrid layer including a first organic part and a first inorganic part and an aluminum oxide layer are laminated;
a second organic-inorganic hybrid layer including a second organic part and a second inorganic part; and
a substrate on which the organic-inorganic mixed layer and the second organic-inorganic hybrid layer are laminated.

2. The gas barrier film according to claim 1, wherein the first organic part included in the first organic-inorganic hybrid layer and the second organic part included in the second organic-inorganic hybrid layer include a hydrocarbon derivative having 5 carbon atoms.

3. The gas barrier film according to claim 1, wherein the first organic-inorganic hybrid layer and the second organic-inorganic hybrid layer include a compound comprising [Al—O—(CH2)5-O]n.

4. The gas barrier film according to claim 1, wherein a thickness of the organic-inorganic mixed layer is selected from a range of 3 nm to 7 nm.

5. The gas barrier film according to claim 1, wherein a thickness of the first organic-inorganic hybrid layer is selected from a range of 3 nm to 7 nm.

6. The gas barrier film according to claim 1, wherein the substrate includes a polymer film having a thickness selected from a range of 10 μm to 100 μm.

7. The gas barrier film according to claim 6, wherein the substrate further includes an aluminum layer that is deposited on the polymer film.

8. The gas barrier film according to claim 7, wherein the substrate further includes a protection layer that is formed on the aluminum layer and includes at least one resin selected from a group including acryl and polyethylene.

9. A method to manufacture a gas barrier film according to an atomic layer deposition process including a method to manufacture a first organic-inorganic hybrid layer, the method comprising:
supplying a first precursor including trimethyl aluminum (TMA) to a substrate and depositing the precursor on to the substrate;
supplying an inert gas to remove at least one of an undeposited first precursor or first reaction byproducts;
supplying a second precursor including a hydrocarbon derivative having 5 carbon atoms to the substrate on which the first precursor is deposited and depositing the precursor on to the substrate; and
supplying the inert gas to remove at least one of an undeposited second precursor or second reaction byproducts.

10. The method according to claim 9, wherein the second precursor includes 1,5-pentanediol.

11. The method according to claim 10, wherein the first organic-inorganic hybrid layer includes a compound comprising [Al—O—(CH2)5-O]n.

12. The method according to claim 9, further comprising:
manufacturing an organic-inorganic mixed layer, wherein manufacturing the organic-inorganic mixed layer includes:
manufacturing a second organic-inorganic hybrid layer in which a first sub-cycle is performed one or more times (X), wherein the first sub-cycle includes:
supplying the first precursor including trimethyl aluminum (TMA) onto the substrate and depositing the precursor on to the substrate;
supplying the inert gas to remove at least one of the undeposited first precursor or first reaction byproducts;
supplying the second precursor including a hydrocarbon derivative having 5 carbon atoms onto the substrate on which the first precursor is deposited and depositing the precursor on to the substrate; and
supplying the inert gas to remove the undeposited second precursor or second reaction byproducts; and
manufacturing an aluminum oxide layer in which a second sub-cycle is performed one or more times (Y), wherein the second sub-cycle includes:
supplying the first precursor including trimethyl aluminum (TMA) onto the substrate and depositing the precursor on to the substrate;
supplying the inert gas to remove at least one of the undeposited first precursor or third reaction byproducts;
supplying the second precursor including water vapor (H₂O) onto the substrate on which the first precursor is deposited and depositing the precursor thereon; and
supplying the inert gas to remove at least one the undeposited second precursor or fourth reaction byproducts.

13. The method according to claim 12, wherein the second precursor used in the method of manufacturing an organic-inorganic mixed layer includes 1,5-pentanediol.

14. The method according to claim 13, wherein the second organic-inorganic hybrid layer includes a compound comprising [Al—O—(CH2)5-O]n.

15. The method according to claim 12, wherein manufacturing the first organic-inorganic hybrid layer and manufacturing the organic-inorganic mixed layer comprises selecting a deposition temperature from a range of temperatures from 22° C. 120° C.

16. The method according to claim 12, wherein manufacturing the first organic-inorganic hybrid layer and manufacturing the organic-inorganic mixed layer comprises selecting a deposition temperature from a range of temperatures from 22° C. 80° C.

17. The method according to claim 12, wherein manufacturing the organic-inorganic mixed layer comprises:
performing a super cycle one or more times (N), wherein the super cycle comprises:
manufacturing a second organic-inorganic hybrid layer in which a first sub-cycle is performed one or more times (X); and
manufacturing an aluminum oxide layer in which the second sub-cycle is performed one or more times (Y).

18. The method according to claim 17, wherein the first sub-cycle is performed one time and the second sub-cycle is performed three times.

19. The method according to claim 18, wherein the first organic-inorganic hybrid layer and the organic-inorganic mixed layer are alternately laminated.

20. The method according to claim 19, wherein the organic-inorganic mixed layer has a thickness selected from a range of thickness from 3 nm to 7 nm.

21. The method according to claim 19, wherein the first organic-inorganic hybrid layer has a thickness selected from a range of thickness from 3 nm to 7 nm.

22. A refrigerator, comprising:
an outer case;
an inner case disposes within the outer case and forming a storage container; and
a vacuum insulation panel disposed between the outer case and the inner case, wherein the vacuum insulation panel comprises a gas barrier film, wherein the gas barrier film comprises:
an organic-inorganic mixed layer on which a first organic-inorganic hybrid layer including a first organic part and a first inorganic part and an aluminum oxide layer are laminated, a second organic-inorganic hybrid layer comprising a second organic part and a second inorganic part, and
a substrate on which the organic-inorganic mixed layer and the second organic-inorganic hybrid layer are laminated.

23. The refrigerator according to claim 22, wherein the first organic part included in the first organic-inorganic hybrid layer and the second organic part included in the second organic-inorganic hybrid layer comprises a hydrocarbon derivative having 5 carbon atoms.

24. The refrigerator according to claim 22, wherein the first organic-inorganic hybrid layer and the second organic-inorganic hybrid layer include a compound comprising [Al—O—(CH2)5-O]n.
